(19) United States
(12) Patent Application Publication
(10) Pub. No.: US 2004/0211882 A1
(43) Pub. Date: Oct. 28, 2004

(54) Image sensor having a rough contact surface

(76) Inventors: Jackson Hsieh, Hsinchu Hsien (TW); Jichen Wu, Hsinchu Hsien (TW); Bruce Chen, Hsinchu Hsien (TW); Bird Lin, Hsinchu Hsien (TW); Worrell Tsai, Hsinchu Hsien (TW); Abnet Chen, Hsinchu Hsien (TW); Tiao-Mu Hsu, Hsinchu Hsien (TW)

Correspondence Address: Keith Kline, PRO-TECHTOR INTERNATIONAL SERVICES, 20775 Norada Court, Saratoga, CA, 95070-3018, US

(21) Appl. No.: 10/422,198

(22) Filed: Apr. 23, 2003

(51) Int. Cl. H01L 27/00

(52) U.S. Cl. 250/208.1

(57) ABSTRACT

An image sensor includes a substrate, a frame layer, a photosensitive chip, and a transparent layer. The substrate has an upper surface formed with a plurality of first connection points, and a lower surface formed with a plurality of second connection points. The frame layer has a first surface and a second surface and is mounted to the upper surface of the substrate with the first surface of the frame layer contacting the upper surface of the substrate so as to form a cavity together with the substrate. The second surface is formed with a rough contact surface. The photosensitive chip is mounted to the upper surface of the substrate and located within the cavity and is electrically connected to the first connection points of the substrate. The transparent layer is adhered to the rough contact surface.

### BACKGROUND OF THE INVENTION

1. Field of the Invention

The invention relates to an image sensor having a rough contact surface, and in particular to an image sensor with enhanced reliability.

2. Description of the Related Art

A general sensor is used to sense signals, which may be optical or audio signals. The sensor of the invention is used to receive image signals or optical signals. After receiving the image signals, the sensor converts the image signals into electrical signals, which are then transmitted to a printed circuit board via a substrate.

Referring to FIG. 1, a conventional image sensor includes a substrate 10, a frame layer 18, a photosensitive chip 26, a plurality of wires 28, and a transparent layer 34. The substrate 10 has an upper surface 12 on which first connection points 15 are formed, and a lower surface 14 on which second connection points 16 are formed. The frame layer 18 has a first surface 20 and a second surface 22 adhered to the upper surface 12 of the substrate 10 to form a cavity 24 together with the substrate 10. The photosensitive chip 26 is arranged within the cavity 24 and is mounted to the upper surface 12 of the substrate 10. Each wire 28 has a first connection point 30 and a second connection point 32. The first connection points 30 are electrically connected to the photosensitive chip 26, and the second connection points 32 are electrically connected to the first connection points 15 of the substrate 10. The transparent layer 34 is adhered to the first surface 20 of the frame layer 18.

The conventional image sensor has the following drawbacks.

Since the area of the first surface 20 of the frame layer 18 is relatively small, the transparent layer 34 cannot be firmly adhered to the frame layer 18, and the reliability of the image sensor is poor.

### SUMMARY OF THE INVENTION

An object of the invention is to provide an image sensor with a rough contact surface to which a transparent layer may be firmly adhered so that the reliability thereof may be improved.

To achieve the above-mentioned object, the invention provides an image sensor including a substrate, a frame layer, a photosensitive chip, and a transparent layer. The substrate has an upper surface formed with a plurality of first connection points, and a lower surface formed with a plurality of second connection points. The frame layer has a first surface and a second surface and is mounted to the upper surface of the substrate with the first surface of the frame layer contacting the upper surface of the substrate so as to form a cavity together with the substrate. The second surface is formed with a rough contact surface. The photosensitive chip is mounted to the upper surface of the substrate and located within the cavity and is electrically connected to the first connection points of the substrate. The transparent layer is adhered to the rough contact surface.

Thus, the transparent layer may be firmly adhered to the rough contact surface of the frame layer.

### BRIEF DESCRIPTION OF THE DRAWINGS

FIG. 1 is a schematic illustration showing a conventional image sensor.

FIG. 2 is a cross-sectional view showing a part of an image sensor of the invention.

FIG. 3 is a cross-sectional view showing the image sensor of the invention.

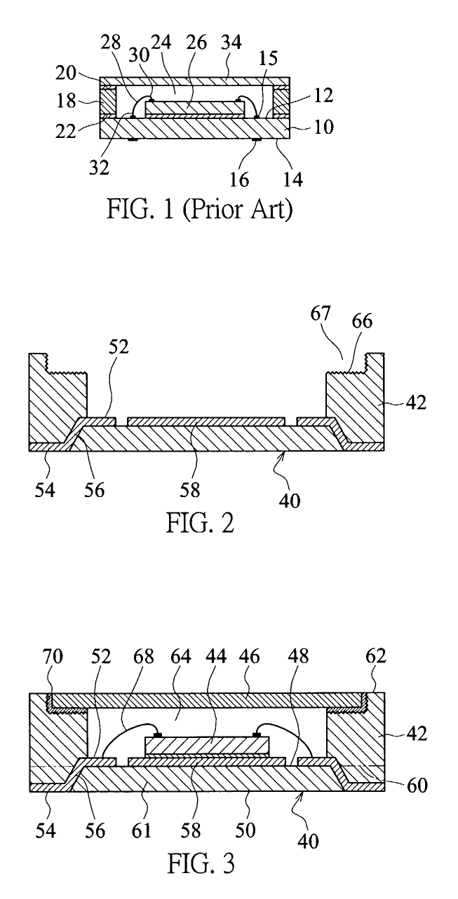

### DETAILED DESCRIPTION OF THE INVENTION

Referring to FIGS. 2 and FIG. 3, an image sensor of the invention includes a substrate 40, a frame layer 42, a photosensitive chip 44, and a transparent layer 46.

The substrate 40 has an upper surface 48 formed with a plurality of first connection points 52, and a lower surface 50 formed with a plurality of second connection points 54. In this embodiment, the substrate 40 includes a plurality of metal sheets 56 arranged in a matrix and a middle board 58. A plastic material 61 is provided to encapsulate the metal sheets 56 and the middle board 58 by way of injection molding with tops of the metal sheets 56 exposed out of the plastic material 61 to form the first connection points 52 and with bottoms of the metal sheets 56 exposed out of the plastic material 61 to form the second connection points 54.

The frame layer 42 has a first surface 60 and a second surface 62 and is mounted to the upper surface 48 of the substrate 40 with the first surface 60 contacting the upper surface 48 so as to form a cavity 64 together with the substrate 40. A depression 67 is formed on the second surface 62 of the frame layer 42 and a rough contact surface 66 is formed inside the depression 67. In this embodiment, the frame layer 42 and the substrate 40 may be integrally injection molded, and the depression 67 and the rough contact surface 66 may be formed on the second surface 62.

The photosensitive chip 44 is mounted to the upper surface 48 of the substrate 40 and located within the cavity 64. A plurality of wires 68 is provided to electrically connect the photosensitive chip 44 to the first connection points 52 of the substrate 40.

The transparent layer 46 is adhered to the rough contact surface 66 of the depression 67 of the second surface 62 of the frame layer 42 by an adhesive 70.

Since the depression 67 is formed with the rough contact surface 66, the contact area between the transparent layer 46 and the rough contact surface 66 may be enlarged, and the transparent layer 46 may be firmly adhered to the frame layer 42. Thus, the reliability of the image sensor package may be enhanced.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. An image sensor, comprising:
a substrate having an upper surface formed with a plurality of first connection points, and a lower surface formed with a plurality of second connection points;
a frame layer having a first surface and a second surface, the frame layer being mounted to the upper surface of the substrate with the first surface of the frame layer contacting the upper surface of the substrate so as to form a cavity together with the substrate, the second surface being formed with a rough contact surface;
a photosensitive chip mounted to the upper surface of the substrate and located within the cavity, the photosensitive chip being electrically connected to the first connection points of the substrate; and
a transparent layer adhered to the rough contact surface.

2. The image sensor according to claim 1, wherein the photosensitive chip is electrically connected to the first connection points of the substrate via a plurality of wires.

3. The image sensor according to claim 1, wherein the second surface of the frame layer is formed with a depression, the rough contact surface is formed inside the depression, and the transparent layer is arranged within the depression to contact the rough contact surface.

4. The image sensor according to claim 1, wherein the substrate comprises a plurality of metal sheets arranged in a matrix and a middle board, which are encapsulated by a plastic material to form the first connection points on tops of the metal sheets and the second connection points on bottoms of the metal sheets.

5. The image sensor according to claim 4, wherein the frame layer and the substrate are integrally formed.
